(19) United States
(12) Patent Application Publication
(10) Pub. No.: US 2024/0083474 A1
(43) Pub. Date: Mar. 14, 2024

(54) ARRANGEMENT, SWITCH, METHOD, COMPUTER SYSTEM, COMPUTER PROGRAM PRODUCT

(71) Applicant: Siemens Aktiengesellschaft, München (DE)

(72) Inventors: Christian Cramer, Burgthann - Ezelsdorf (DE); Philipp Kunze, Nürnberg (DE); Martin Streubühr, Zirndorf (DE); Klaus Groth, Hersbruck (DE)

(21) Appl. No.: 18/367,151

(22) Filed: Sep. 12, 2023

(30) Foreign Application Priority Data
Sep. 14, 2022 (EP) 22195682.4

(51) Int. Cl. B61J 3/12

(52) U.S. Cl. CPC B61J 3/12

(57) ABSTRACT

An arrangement including a guide system and a carrier vehicle. The guide system includes a route guide extending along a path for the carrier vehicle. To provide a flexible and rapid material flow in a production, the guide system has vehicle guide elements on the carrier vehicle. The guide system further includes vehicle guide elements on the carrier vehicle. The guide system is configured in such a way that a guide function of the guide system limits the degree of freedom of the translational movability of the carrier vehicle during the interaction of the route guide with the vehicle guide elements apart from a limited movement play to a translational movability along the path. The guide function may be cancelled at least in portions along the path by a movability of the route guide out of a guide position and may be activated by a movability of the route guide into the guide position.

### CROSS REFERENCE TO RELATED APPLICATIONS

This application claims the benefit of EP 22195682, filed on Sep. 14, 2022, which is hereby incorporated by reference in its entirety.

### FIELD

Embodiments relate to an arrangement of a production facility, including a guide system, a carrier vehicle, the carrier vehicle being provided for the automatic transportation of materials or workpieces in the production facility, the guide system having a route guide, extending along a path, for the carrier vehicle.

### BACKGROUND

In production facilities, emphasis is increasingly placed on flexibility and individualization in addition to throughput. This presupposes a flexible machine layout, in the case of which material flows are separated and brought together, in order to make processing possible which is individual but also in parallel. In the context of guide systems, for example including linear motor systems, the process speed has to be considered, above all.

Great process forces may arise at processing stations, and high repeat accuracies are necessary. This places high requirements on the guide systems. Linear motors with precise and rigid mechanical guidance are advantageous. Rigid mechanical guides have the property that they are mounted throughout the complete linear motor system and consist of inflexible materials. The separating and bringing together of material flows is possible on rigid guides only by way of a considerable decrease in the process speed.

This problem may be solved by classic forwarding of products via a handling unit such as a picker or via more simple mechanisms. This method disadvantageously has a low process speed.

Another possibility is to design the transfer apparatus as a holding apparatus on the carrier vehicle, or to carry out the transfer from one linear motor system to another linear motor system by way of the product being clamped in between carrier vehicles. The two linear motor systems operate completely separately from one another here. This limits the possibilities of fastening the product on the carrier vehicle, however, and presupposes a certain minimum size and composition of the product. For example, the product must not consist of a flexible material (for example, foam).

One example for a transfer of this type of the products is shown by the facility with the brand name “Beckhoff XTS” from the company Beckhoff Automation GmbH & Co. KG (see, for example, at: https://www.beckhoff.com/de-de/produkte/motion/xts-linearer-produkttransport/).

The company B&R Industrial Automation GmbH offers a flexible rail system with the designation “Acopostrak” including a purely electromagnetically operating high-speed switch, by way of which product streams may be separated and brought together again at full speed (https://www.br-automation.com/en/products/mechatronic-systems/acopostrak/). Two linear motor paths are attached here so as to lie opposite one another. If a carrier vehicle is intended to change path, a current which weakens the magnetic field is applied on one side and a current which increases the field is applied on the other side. The carrier vehicle (carrier) is therefore attracted magnetically to the other side.

JP 5 040271 B2 has discloses a guide system without movable path guide elements.

FR 2 197 087 A1 has already disclosed a guide system for passenger trains.

Further guide systems are already known from U.S. Pat. No. 6,095,054 A, US 2013/313070 A1, JP H03 7003 A and JP 2001 057712 A.

### BRIEF SUMMARY AND DESCRIPTION

The scope of the present invention is defined solely by the appended claims and is not affected to any degree by the statements within this summary. The present embodiments may obviate one or more of the drawbacks or limitations in the related art.

Embodiments provide efficient, rapid and precise handling of materials and workpieces in a production facility possible.

Embodiments provide where the guide system is configured in such a way that a guide function of the guide system limits the degree of freedom of the translational movability of the carrier vehicle during the interaction of the route guide with the vehicle guide elements apart from a limited movement play to a translational movability along the path, the guide function (a) may be cancelled at least in portions along the path by a movability of the route guide out of a guide position, and (b) may be activated by a movability of the route guide into the guide position.

An arrangement is, for example, an arrangement of a production facility. A production facility of this type may have, for example, an integrated automated material or workpiece logistics system that operates on the basis of the arrangement. The arrangement may exist multiple times in a production facility of this type, a multiplicity of carrier vehicles each transporting individual or a plurality of workpieces or materials. Here, a switch makes it possible for the transported streams to be separated or to be combined.

An arrangement may be used in a flexible manner, and makes efficient, rapid and precise handling of the workpieces possible, even in the case of batch sizes of 1.

Carrier vehicles are also frequently called carriers or workpiece carriers, and are provided for the automatic transportation of materials or workpieces in a production facility. These carrier vehicles do not have to have a dedicated drive but may also develop propulsion forces in interaction with a route or a guide system.

One embodiment provides that a linear motor route is configured along the path, which linear motor route interacts magnetically with magnets that are attached to the carrier vehicle, with the result that the carrier vehicle may be driven along the path as a result.

One embodiment provides that the vehicle guide elements have at least one, two, or at least four rollers, and the route guide has at least one, for example two rails, each rail interacting the at least one roller. The rollers are configured and paired with the rails in such a way that a movement transversely with respect to the direction of travel is restricted. The shape of the roller is configured in each case to the shape of the rail in such a way that the roller may be removed from the rail transversely with respect to the direction of travel only in an angular window of at most 90° along a removal direction. In the case, for example, of a use of two rails per guide system along a path of a carrier vehicle, the rails are arranged in such a way that, in the case of an activated guide function, the respective removal direction of the carrier vehicle is blocked by the rails. In accordance with one embodiment, the two rails may be arranged in an opposed manner with regard to the angular window of the respective removal directions, with the result that the degree of freedom that is required for the removal is blocked in the case of an activated guide function.

In accordance with one embodiment, the activation or cancelation of the guide function may take place by a movability of the path guide. To this end, it is that the path guide is removed from the respective vehicle guide element (for example in portions of the route) for cancelation and is moved closer to it for activation. This movement may be driven by way of an electromagnetic actuator. As an alternative, a pneumatic or hydraulic drive is also possible.

In accordance with one embodiment, the rails may have a contact surface of concave cross section with respect to the rollers, and the rollers may have a correspondingly convex contact surface that results in a restriction of the angular range of the possible removal directions. A reversed design with regard to the rail cross section and the roller cross section is also possible in each case here.

To make a transfer between the different paths that are configured as linear motor routes possible, a common overlapping parallel region of the paths may be provided. In the present case, this is also called a switch or a switch portion. A switch with an arrangement or in accordance with the embodiment provides that the guide system has, for the carrier vehicle, a first route guide extending along a first path and a second route guide extending along a second path. It is expedient here if the carrier vehicle has first vehicle guide elements for the first route guide and second vehicle guide elements for the second route guide, the two route guides and vehicle guide elements being arranged in such a way that the paths of the transport vehicle along a switch portion are identical.

The paths, for example the paths involved in the switch, have a mechanical guide system.

It is a characteristic of the overlapping region with two routes (switch for short) that the carrier vehicle may be in engagement with the two mechanical guide systems and has to be permanently in engagement with at least one guide system. The carrier vehicle may also temporarily be in engagement with the two guide systems at the same time.

In detail, a method for the transfer of a carrier vehicle by an arrangement or a switch or according to an embodiment provides that the carrier vehicle is transferred from a first route guide along a first path to a second route guide along a second path. During the transfer, the guide function is always activated either by the first vehicle guide elements on the first route guide or by the second vehicle guide elements on the second route guide, or the two vehicle guide elements are activated on the respective route guide.

In the case of a switch with an arrangement, at least one of the two routes is configured as a linear motor route of this type along the path. The second route may consist along the path of a linear motor system or a pure guide system. The two routes of the parts have the features for controlling (that is to say, for activation or cancellation) of the guide system.

By the controlling of the guide system, the carrier vehicle may change the path and possibly the linear motors.

The controlling takes place, for example, by retractable or adjustable vehicle guide elements.

One embodiment provides a computer-implemented method for the simulation of the machine or according to one of its embodiments. To this end, a computer system including at least one computer is configured and prepared for the simulation according to the method. The computer or the computer system may be prepared for this purpose by a corresponding computer program product for carrying out a method according to one of its embodiments.

### BRIEF DESCRIPTION OF THE FIGURES

FIG. 1 depicts a diagrammatic plan view of paths in the region of a switch portion with an arrangement according to an embodiment.

FIG. 2 depicts a diagrammatic, simplified cross-sectional illustration of an arrangement according to an embodiment.

FIG. 3 depicts a diagrammatic, simplified cross-sectional illustration of an alternative arrangement according to an embodiment.

FIG. 4 depicts a diagrammatic, simplified three-dimensional illustration of a detail IV from FIG. 3 according to an embodiment.

FIG. 5 depicts a diagrammatic illustration of a simulation, running on a computer of the operation of an inductance according to an embodiment.

### DETAILED DESCRIPTION

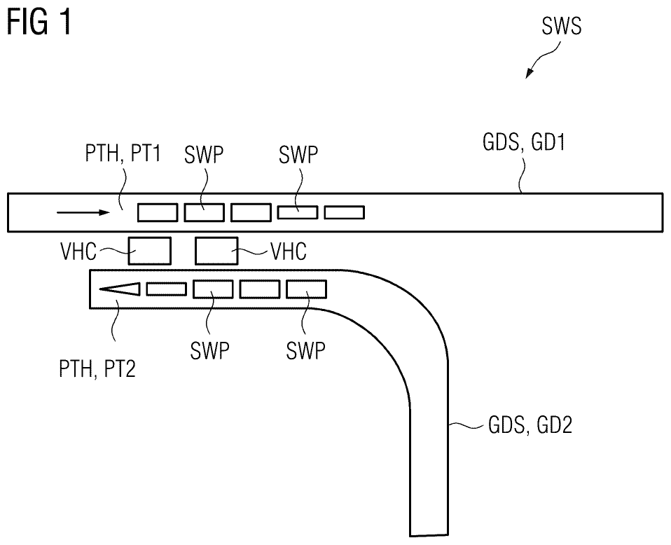

FIG. 1 depicts a diagrammatic plan view of two paths PTH in the region of a switch portion SWS with an arrangement ARR. A guide system GDS for carrier vehicles VHC extends along a first path PT1 as a first route guide GD1.

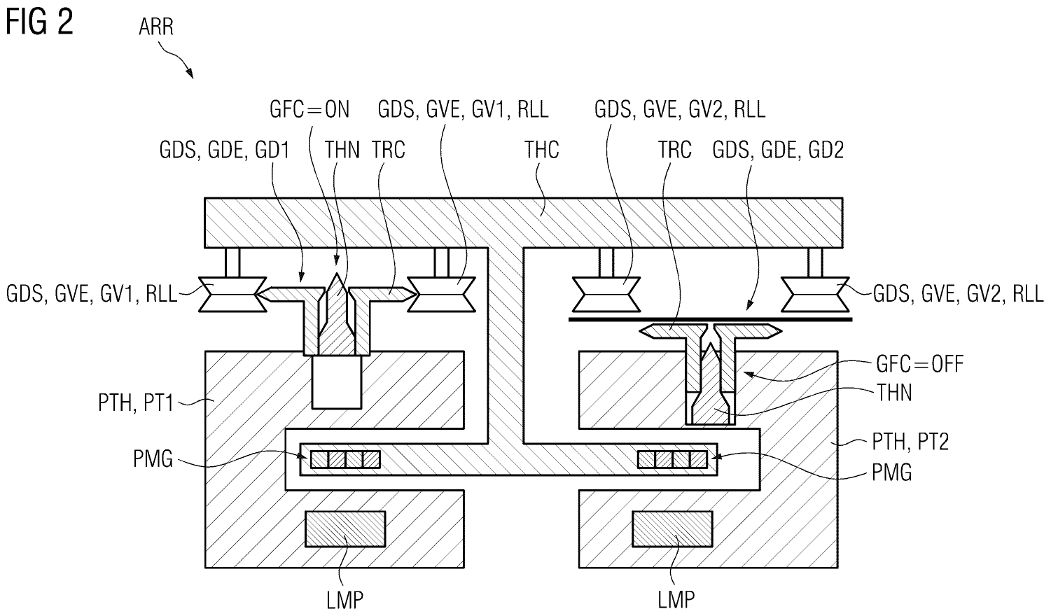

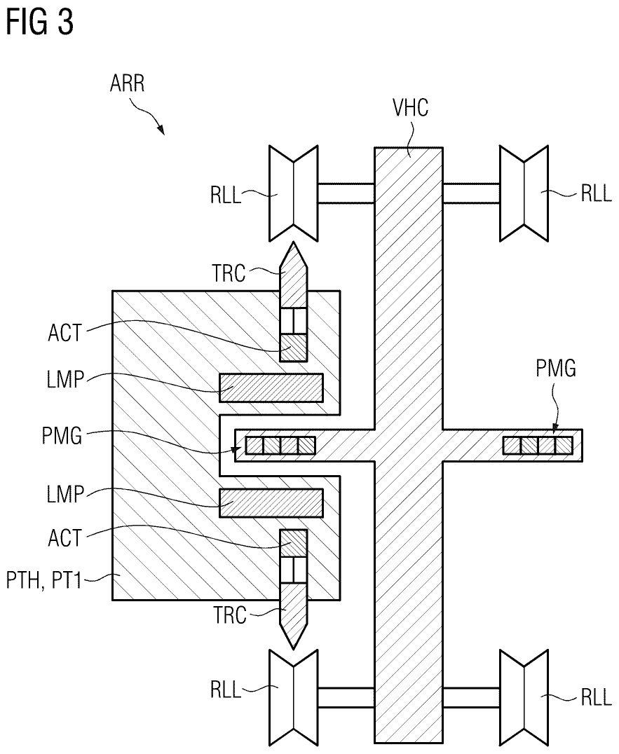

FIGS. 2 and 3 each show an arrangement ARR in greater detail in cross section through the carrier vehicle VHC and the guide systems GDS of the two route guides GDE along the paths PTH.

The arrangement ARR includes a guide system GDS and a carrier vehicle VHC. The guide system GDS includes in each case one route guide GDE for each path PTH and vehicle guide elements GVE for each path PTH on each carrier vehicle VHC.

The guide system GDS has vehicle guide elements GVE on the carrier vehicle VHC. The guide system GDS is configured in such a way that a guide function GFC of the guide system GDS limits the degree of freedom of the translational movability of the carrier vehicle VHC during the interaction of the route guide GDE with the vehicle guide elements GVE apart from a limited movement play to a translational movability along the path PTH.

The guide function GFC may be cancelled (GFC=OFF) or activated (GFC=ON) at least in portions along the path PTH. This may be realized by a movability of the vehicle guide elements GVE and/or the route guide GDE. FIGS. 2 and 3 show how the movability of the route guide GDE makes an activation (GFC=ON) or cancelation (GFC=OFF) of the guide function GFC possible.

FIGS. 2 and 3 depict the guide system GDS of the arrangement ARR in each case twice in the region of the switch portion SWS. Here, the guide system GDS has, for the carrier vehicle VHC, a first route guide GD1 extending along a first path PT1 and a second route guide GD2 extending along a second path PT2.

The carrier vehicle VHC has first vehicle guide elements GV1 for the first route guide GD1 and second vehicle guide elements GV2 for the second route guide GD2. The two route guides GD1, GD2 and vehicle guide elements GV1, GV2 are arranged in such a way that the paths PT1, PT2 of the carrier vehicle VHC are identical along the switch portion SWS.

A linear motor route LMP that interacts magnetically with magnets PMG attached to the carrier vehicle VHC is configured in each case along the paths PT1, PT2. In this way, the carrier vehicle VHC may be driven along the respective path PTH. In the switch portion SWS, it is sufficient for the drive if only one path PT1, PT2 is configured as a linear motor route LMP.

During a transfer of the carrier vehicle VHC from one path PTH to another in a switch portion SWS, it is characteristic that the mechanical guide system GDS of the two paths PTH may be in engagement, and the guide system GDS of at least one path PTH should be permanently in engagement. The guide system GDS of the two paths PTH may be in engagement at times.

A sequence for a change of the path PTH in the switch portion SRS may take place in the following steps:
1. The carrier vehicle VHC moves along the first path PT1 into a switch portion SWS.
2. Activate guide function GFC for the second path PT2, with the result that the two guide functions GFC are active.
3. Cancel guide function GFC for the first path PT1.
4. Further travel of the carrier vehicle VHC along the second path PT2.
5. As soon as the carrier vehicle VHC has left the switch portion SWS, the next carrier vehicle VHC may move into it.

FIG. 2 depicts a plurality of mandrels THN that may be controlled electromechanically along the switch portion SWS, engage or disengage between spreadable route guide GDE configured as two opposite rails TRC, and engage or disengage selectively into/out of vehicle guide elements GVE configured as rollers RLL. The controlled mandrels THN not only spread the rails TRC into the guide function GFC, but also ensure a removal of the rails TRC from the region of the rollers or vehicle guide elements GVE in the case of cancelling of the guide function GFC. An electromechanical drive of the mandrels THN is not shown in FIG. 2.

FIG. 3 depicts a somewhat simpler depiction of the arrangement ARR with the rails TRC, retractable in portions, of the route guide GDE. Actuators ACT make it possible here on opposite sides for the rails TRC to move closer to the rollers RLL or to move away from the latter. For the sake of simplicity, the route guide GDE is shown only on the left-hand side.

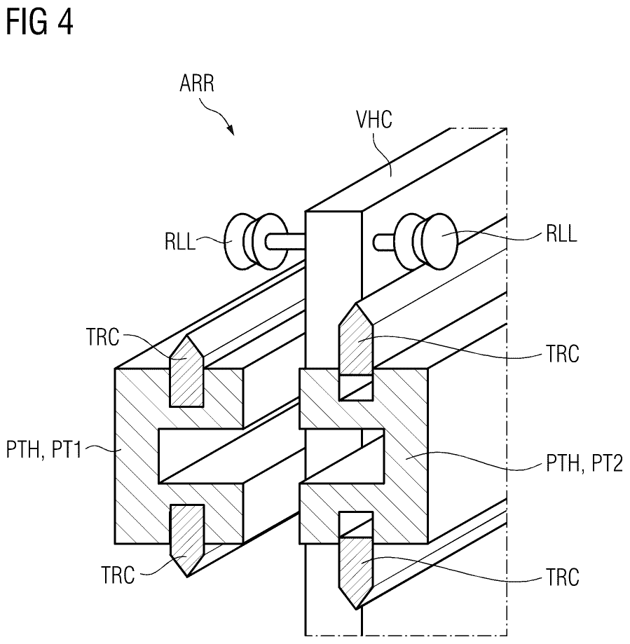

To illustrate the extent of the route guide GDE with rails TRC along the path PTH, FIG. 4 depicts the route guide GDE and, in part, a carrier vehicle VHC in a simplified three-dimensional manner.

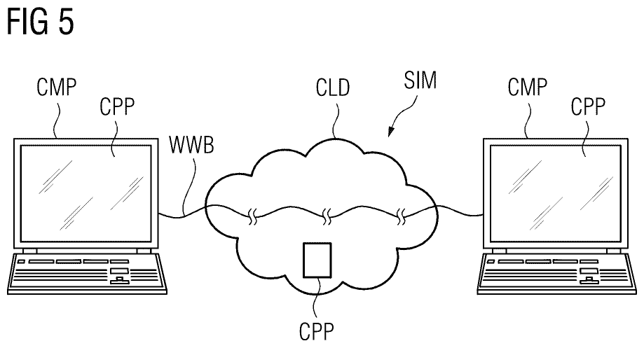

FIG. 5 depicts a diagrammatic illustration of a simulation SIM of the arrangement ARR or switch, which simulation SIM runs on a computer CMP, here on a plurality of computers CMP of a network WWB including a cloud CLD. The software installed on the computers CMP is a computer program product CPP that, when run on at least one computer CMP, makes it possible for a user to influence or configure and gain knowledge on the basis of the executed simulation SIM by interfaces, for example by screen and keyboard, with the result that, for example, technical design decisions may be assisted and verified by the simulation.

It is to be understood that the elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present invention has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. An arrangement of a production facility comprising:
a carrier vehicle, the carrier vehicle provided for automatic transportation of materials or workpieces in the production facility;
a guide system comprising a route guide extending along a path for the carrier vehicle, the guide system further comprising vehicle guide elements on the carrier vehicle;
wherein the guide system is configured in such a way that a guide function of the guide system limits a degree of freedom of a translational movability of the carrier vehicle during an interaction of the route guide with the vehicle guide elements apart from a limited movement play to a translational movability along the path and the guide function may be cancelled at least in portions along the path by a movability of the route guide out of a guide position, and may be activated by a movability of the route guide into the guide position.

2. The arrangement of claim 1, further comprising:
a linear motor route configured along the path, wherein the linear motor route interacts magnetically with magnets that are attached to the carrier vehicle, wherein the carrier vehicle may be driven along the path using the linear motor route.

3. The arrangement of claim 1, wherein the guide system is a mechanical guide system.

4. The arrangement of claim 1, wherein the vehicle guide elements comprise at least two rollers and the route guide comprises two rails.

5. The arrangement of claim 1, wherein an activation or a cancelation of the guide function taking place by a movability of the route guide.

6. The arrangement of claim 1, wherein the route guide comprises a translationally movable configuration at least in a switch portion transversely with respect to the path for an activation or a cancelation of the guide function.

7. A switch comprising:
an arrangement comprising:
a carrier vehicle, the carrier vehicle provided for automatic transportation of materials or workpieces in a production facility; and
a guide system comprising a route guide extending along a path for the carrier vehicle, the guide system further comprising vehicle guide elements on the carrier vehicle;
wherein the guide system is configured in such a way that a guide function of the guide system limits a degree of freedom of a translational movability of the carrier vehicle during an interaction of the route guide with the vehicle guide elements apart from a limited movement play to a translational movability along the path and the guide function may be cancelled at least in portions along the path by a movability of the route guide out of a guide position, and may be activated by a movability of the route guide into the guide position;
wherein the guide system further comprises, for the carrier vehicle, a first route guide extending along a first path and a second route guide extending along a second path, wherein the carrier vehicle comprises first vehicle guide element for the first route guide and second vehicle guide element for the second route guide, wherein the first route guide, the second route guide, the first vehicle guide element and the second vehicle guide element are arranged in such a way that paths of the carrier vehicle along a switch portion are identical.

8. A method for a transfer by a first route guide along a first path to a second route guide along a second path of a carrier vehicle by an arrangement comprising the carrier vehicle, the carrier vehicle provided for automatic transportation of materials or workpieces in a production facility and a guide system comprising a route guide extending along a path for the carrier vehicle, the guide system further comprising vehicle guide elements on the carrier vehicle, wherein the guide system is configured in such a way that a guide function of the guide system limits a degree of freedom of a translational movability of the carrier vehicle during an interaction of the route guide with the vehicle guide elements apart from a limited movement play to a translational movability along the path and the guide function may be cancelled at least in portions along the path by a movability of the route guide out of a guide position, and may be activated by a movability of the route guide into the guide position, the method comprising:
activating the guide function during the transfer either by a first vehicle guide element on the first route guide or by a second vehicle guide element on the second route guide, or
activating the first vehicle guide element and the second vehicle guide element on the respective route guide.
